(19) United States
(12) Patent Application Publication
(10) Pub. No.: US 2023/0115975 A1
(43) Pub. Date: Apr. 13, 2023

(54) BATTERY APPARATUS AND CONTROL METHOD THEREOF

(71) Applicant: SAMSUNG SDI CO., LTD., Yongin-si (KR)

(72) Inventor: Taeho KIM, Yongin-si (KR)

(21) Appl. No.: 17/963,558

(22) Filed: Oct. 11, 2022

(30) Foreign Application Priority Data
Oct. 13, 2021 (KR) 10-2021-0135989

(51) Int. Cl. H01M 10/42; H01M 10/48; G01R 31/396; H02J 7/00

(52) U.S. Cl. CPC H01M 10/425; H01M 10/482; H01M 10/486; G01R 31/396; H02J 7/0014; H01M 2010/4271; H01M 2010/4278

(57) ABSTRACT

An embodiment provides a battery apparatus including: a battery module including a plurality of battery cells; and a battery management system that receives operation information including mode information and task information about an operation being performed by the battery module from the battery module and that generates a control signal with respect to the battery module based on the operation information to transmit it to a battery module connected thereto. Wherein one mode includes a plurality of tasks of which order is predetermined.

### CROSS-REFERENCE TO RELATED APPLICATION

This application claims priority to and the benefit of Korean Patent Application No. 10-2021-0135989 filed in the Korean Intellectual Property Office on Oct. 13, 2021, the entire contents of which are incorporated herein by reference.

### BACKGROUND

### 1. Field

Embodiments relate to a battery apparatus and a control method thereof.

### 2. Description of the Related Art

A battery management system and a plurality of battery modules may transmit and receive data through wires. The battery module may perform an operation corresponding to an instruction of the battery management system.

### SUMMARY

An embodiment provides a battery apparatus including: a battery module including a plurality of battery cells; and a battery management system that receives operation information including mode information and task information about an operation being performed by the battery module from the battery module and that generates a control signal with respect to the battery module based on the operation information to transmit it to a battery module connected thereto. Herein, one mode includes a plurality of tasks of which order is predetermined.

The operation information may further include information about at least one of a temperature and a voltage of a battery cell of each of the battery modules, and when the mode information indicates a default mode indicating that there is no operation being performed by the battery module, the battery management system may generate a control signal based on the information about at least one of the temperature and the voltage of each battery cell.

When it is determined that there is a next task after the task corresponding to the task information in a mode corresponding to the mode information, the battery management system may generate a control signal controlling the battery module so that the battery module performs the next task.

When it is determined that there is no next task after the task corresponding to the task information in a mode corresponding to the mode information, the battery management system may generate a control signal controlling the battery module so that the battery module performs a first task of the mode.

The mode may include at least one of a battery management system initializing mode, a battery module manager initializing mode, a measurement mode, a diagnosis mode, a cell balancing mode, an error mode, and a default mode.

Another embodiment provides a control method of a battery apparatus, including: transmitting, by a battery module including a plurality of battery cells, operation information on an operation being performed to a battery management system, wherein the operation information includes mode information and task information, and one mode includes a plurality of operations of which order is predetermined; generating, by the battery management system, a control signal with respect to the battery module based on the operation information; and transmitting, by the battery management system, the control signal to the battery module.

The operation information may further include: information about at least one of a temperature and a voltage of a battery cell of each of the battery modules; the transmitting of the operation information to the battery management system may include transmitting, by the battery module, operation information including mode information indicating a default mode indicating that there is no operation being performed by the battery module, to the battery management system; and the generating of the control signal may include generating, by the battery management system, a control signal based on information on at least one of a temperature and a voltage of each of the battery cells when the mode information indicates the default mode.

The generating of the control signal may include generating, by the battery management system, when it is determined that there is a next task after the task corresponding to the task information in a mode corresponding to the mode information, a control signal controlling the battery module so that the battery module performs the next task.

The generating of the control signal may include generating, by the battery management system, when it is determined that there is no next task after the task corresponding to the task information in a mode corresponding to the mode information, a control signal controlling the battery module so that the battery module performs a first task of the mode.

The mode may include at least one of a battery management system initializing mode, a battery module manager initializing mode, a measurement mode, a diagnosis mode, a cell balancing mode, an error mode, and a default mode.

### BRIEF DESCRIPTION OF THE DRAWINGS

Features will become apparent to those of skill in the art by describing in detail example embodiments with reference to the attached drawings in which:

FIG. 1 illustrates a battery apparatus according to an example embodiment.

FIG. 2 illustrates a battery module and a battery management system of a battery apparatus according to an example embodiment in more detail.

FIG. 3 illustrates a mode and a task corresponding to the mode in a battery apparatus according to an example embodiment.

FIG. 4 illustrates an example of an operation flowchart when a battery management system is connected to a battery module, in a battery apparatus according to an example embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey example implementations to those skilled in the art. In the drawing figures, the dimensions of layers and regions may be exaggerated for clarity of illustration. Like reference numerals refer to like elements throughout.

The terms “module” and/or “unit, portion, or part” representing constituent element used in the following description are used only in order to make understanding of the specification easier, and thus, these terms do not have meanings or roles that distinguish them from each other by themselves.

Terms including an ordinal number, such as first, second, etc., may be used to describe various elements, but the elements are not limited by the terms. The terms are only used to differentiate one constituent element from other constituent elements.

It should be understood that, when it is described that an element is “coupled” or “connected” to another element, the element may be “directly coupled” or “directly connected” to the another element, or may be “coupled” or “connected” to the other element through a third element. In contrast, it should be understood that, when it is described that an element is “directly coupled” or “directly connected” to another element, no element is present between the element and the other element.

In the present application, it should be understood that the term “include”, “comprise”, “have”, or “configure” indicates that a feature, a number, a step, an operation, a constituent element, a part, or a combination thereof described in the specification is present, but does not exclude a possibility of presence or addition of one or more other features, numbers, steps, operations, constituent elements, parts, or combinations, in advance.

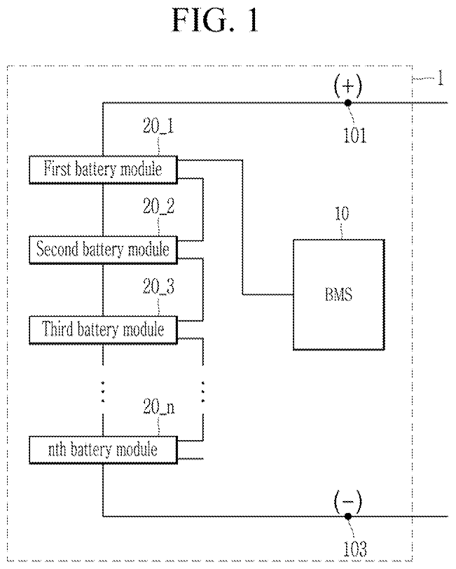

FIG. 1 illustrates a battery apparatus according to an example embodiment.

A battery apparatus 1 may include a battery management system 10 and a plurality of battery modules 20_1 to 20_n.

The battery management system 10 and the plurality of battery modules 20_1 to 20_n may transmit and receive data through communication such as UART or CAN communication.

The battery management system 10 may be connected to one battery module 20_i (i is one of natural numbers from 1 to n) of the plurality of battery modules 20_1 to 20_n to transmit a control signal, for controlling an operation of the battery module 20_i, to the battery module 20_i.

The plurality of battery modules 20_1 to 20_n may be connected in, e.g., series to supply desired power to connection terminals 101 and 103 of the battery apparatus 1.

The plurality of battery modules 20_1 to 20_n may be connected to the battery management system 10 through respective wires.

FIG. 1 illustrates a case in which the first battery module 20_1 is connected to the battery management system 10. The battery management system 10 and the plurality of battery modules 20_1 to 20_n may be connected by using a daisy chain method.

Each battery module 20_i may transmit information on an operation state of the battery module 20_i to the battery management system 10.

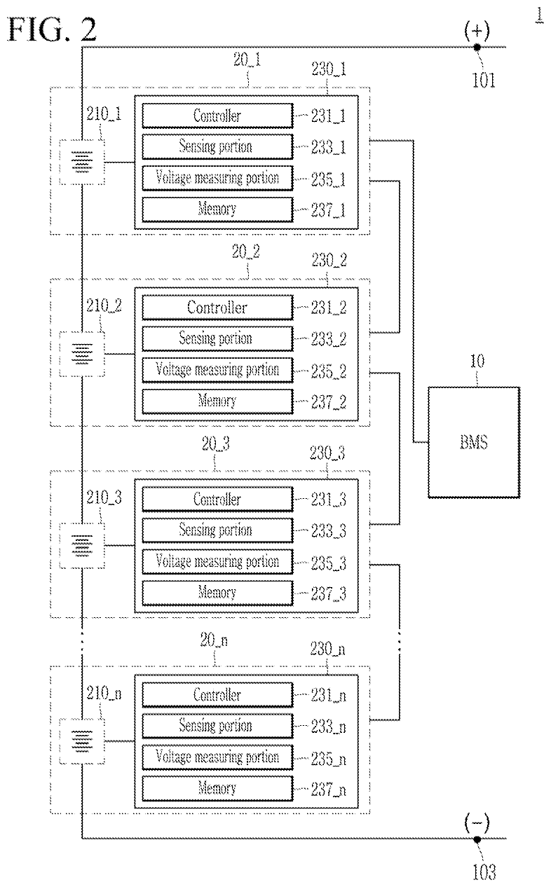

FIG. 2 illustrates the battery module 20_i and the battery management system 10 of the battery apparatus 1 according to an example embodiment in more detail.

Referring to FIG. 2, the battery module 20_i may include a plurality of battery cells 210_i and a plurality of corresponding battery module managers (BMM) 230_i.

The plurality of battery cells 210_i may be rechargeable secondary batteries. The plurality of battery cells 210_i may be connected in, e.g., series to form the battery module 20_i.

The plurality of battery module managers 230_i may each include a controller 231_i, a sensing portion 233_i that measures a temperature of the battery cell 210_i, a voltage measuring portion 235_i that measures a voltage of each of the battery cells 210_i, and a memory 237_i.

The controller 231_i may control overall constituent elements of the corresponding battery module 20_i to perform an operation corresponding to the control signal based on the control signal received from the battery management system 10.

The sensing portion 233_i may measure a cell temperature of each of the corresponding plurality of battery cells 210_i. The sensing portion 233_i may generate a voltage signal or a current signal indicating the measured cell temperature to transmit it to the controller 231.

The voltage measuring portion 235_i may measure a cell voltage of each of the corresponding plurality of battery cells 210_i. The voltage measuring portion 235_i may generate a voltage signal or a current signal indicating the measured cell voltage to transmit it to the controller 231.

The memory 237_i may include data used for the controller 231_i to control the corresponding battery module 20_i. In addition, the memory 237_i may include operation information on an operation state currently being performed by the corresponding battery module 20_i.

The operation information may include mode information and task information on a task to be performed or being performed by the battery module 20_i in each mode. Furthermore, the operation information may include information on the cell temperature measured by the sensing portion 233_i, the cell voltage measured by the voltage measuring portion 235_i, and the like.

The controller 231_i may transmit operation information of the battery module 20_i to the battery management system 10 according to a request of the battery management system 10.

The battery management system 10 may generate a control signal for controlling the battery module 20_i based on the operation information received from the battery module manager 230_i. For example, the battery management system 10 may generate the control signal based on mode information and task information, a cell voltage, and a cell temperature included in the operation information.

The control signal may include information on a mode to be performed in the future by the battery module 20_i and a task corresponding thereto. One mode may include a plurality of tasks whose order is predetermined. The battery management system 10 may determine an operation required for the battery module 20_i based on the operation information to generate a control signal corresponding thereto. Each mode and the task corresponding thereto may be stored in advance in the battery management system 10.

For example, the battery management system 10 may detect a cell requiring cell balancing based on a plurality of cell voltages included in the operation information, and may generate a control signal for performing a cell balancing operation.

By way of background, a general battery management system may generate a control signal corresponding to each task so that each battery module performs operations included in any one mode. In addition, the battery management system may transmit a control signal corresponding to each battery module. When the battery module manager receives a corresponding control signal from the battery management system, the battery module manager may control the battery module to perform the task corresponding to the control signal. However, it is possible that the battery management system and the battery module may be disconnected, e.g., from one another, while the battery module is performing a task included in a mode corresponding to the control signal. In this case, in order for the battery module to proceed to a next task of the corresponding mode, it must receive a control signal corresponding to the next task from the battery management system but, since the battery management system and the battery module are disconnected, the battery module does not receive a new control signal from the battery management system. Thus, it continuously performs the task corresponding to the control signal received directly before they are disconnected.

In contrast, as will now be described, an example embodiment may provide a battery management system and a battery apparatus that may control a battery module to continuously operate even when the battery management system and the battery module are disconnected and then reconnected.

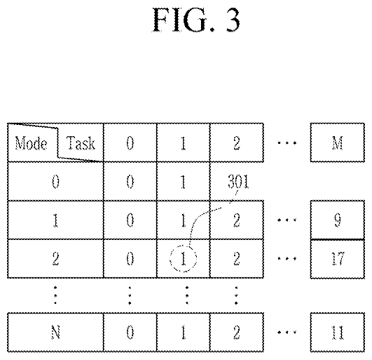

Hereinafter, mode information and task information included in operation information will be described with reference to FIG. 3.

FIG. 3 illustrates a mode and a task corresponding to the mode in the battery apparatus 1 according to an example embodiment.

Referring to FIG. 3, the battery apparatus 1 may operate in a plurality of modes, which may include a battery management system 10 initializing mode, a battery module manager 230_i initializing mode, a measurement mode, a diagnosis mode, a cell balancing mode, an error mode, and a default mode.

In addition, there may be a mode in which the battery module manager 230_i performs emergency discharge of the battery cell 210_i, e.g., for 10 seconds.

In addition, each mode may include M (M is a natural number) sequential tasks required to perform each mode.

The battery management system 10 initializing mode may include a task of initializing all data stored in the battery management system 10, and then a task of connecting the battery management system 10 and the battery module manager 230_i. For example, there may be a case in which a power source is connected to the battery management system 10.

The battery module manager 230_i initializing mode may include a task of initializing all data stored in the battery module manager 230_i. This may be performed while the battery management system 10 initializes all data stored in the battery management system 10 or during an arbitrary operation. For example, when the battery management system 10 detects an abnormal operation of the battery module manager 230_i, it may generate a control signal including the battery module manager 230_i initializing mode.

The measurement mode may include at least one of a task in which the sensing portion 233_i of the battery module manager 230_i measures a cell temperature, or a task in which the voltage measuring portion 235_i measures a cell voltage.

The diagnosis mode may include a task in which the battery management system 10 checks whether there is an abnormality in a specific item set in advance in the battery module manager 230_i. For example, the diagnosis mode may include a charging pump confirmation task, a sensing portion confirmation task, a balancing switch confirmation task, an ADC confirmation task, and a communication data confirmation task.

The cell balancing mode may include a series of tasks used for cell balancing of the battery module 20_i.

The error mode may include a task performed by the battery management system 10 when an abnormality is detected during operation. For example, when the battery management system 10 detects deterioration in reliability of data collected from the battery module manager 230_i, an error may be detected in communication with the battery module manager 230_i.

Referring to item 301 of the example of FIG. 3, the battery management system 10 may transmit a control signal for controlling the battery module 20_i to perform task 1 of mode 2 to the battery module 20_i. The battery module 20_i may perform an operation corresponding to task 1 of mode 2 based on the received control signal. Here, the operation corresponding to task 1 may be an operation of measuring a battery cell temperature or an operation of measuring a cell voltage.

The battery management system 10 may receive a report on completion of task 1 from the battery module 20_i, or may control the battery module 20_i to perform a next task after a predetermined time has elapsed from starting of task 1. That is, the battery management system 10 may generate a control signal for controlling to perform task 2 of mode 2 to transmit the generated control signal to the battery module 20_i. The battery module 20_i may perform an operation corresponding to task 2 of mode 2 based on the received control signal.

In the example in FIG. 3, when the battery management system 10 controls the battery module 20_i in mode 2, the battery management system 10 may generate 17 control signals to transmit them to the battery module 20_i so that the battery module 20_i performs up to an operation corresponding to task 17 of mode 2.

When the battery management system 10 and the battery module 20_i are disconnected, the battery module 20_i may repeatedly perform an operation corresponding to a control signal last received from the battery management system 10. In this case, when the battery management system 10 and the battery module 20_i are connected again, the battery module 20_i may transmit operation information including task information and mode information corresponding to the operation being performed to the battery management system 10.

For example, when the battery management system 10 and the battery module 20_i are disconnected after the control signal for controlling the battery management system 10 to perform the operation corresponding to task 2 of mode 2 is transmitted to the battery module 20_i, the battery module 20_i may continuously perform the operation corresponding to task 2 of mode 2. Thereafter, when the battery management system 10 and the battery module 20_i are connected again, the battery module 20_i may transmit operation information including information on mode 2 and information on task 2 corresponding to the currently performed operation to the battery management system 10.

The battery management system 10 may confirm that the battery module 20_i performs the operation corresponding to operation information including information on mode 2 and information on task 2 based on the operation information of the battery module 20_i. Accordingly, the battery management system 10 may generate a control signal so that the battery module 20_i performs an operation corresponding to task 3, which is a next step of task 2 in mode 2. Accordingly, the continuity of the operation of the battery module 20_i may be maintained.

When the battery management system 10 and the battery module 20_i are disconnected after the control signal for controlling the battery management system 10 to perform mode 2 and task 17 is transmitted to the battery module 20_i, the battery module 20_i may continuously perform the operation corresponding to task 17 of mode 2. Thereafter, when the battery management system 10 and the battery module 20_i are connected again, the battery module 20_i may transmit operation information including information on mode 2 and information on task 17 to the battery management system 10. However, as shown in FIG. 3, there is no next task of task 17 in mode 2. Accordingly, the battery management system 10 may generate a control signal for controlling to perform task 0, which is the first task of the corresponding mode, rather than a control signal for performing the next task of the operation being performed. Thus, the battery module 20_i may next perform an operation corresponding to task 0 of mode 2.

When the battery module 20_i is performing no operation, the battery module 20_i may transmit, to the battery management system 10, operation information including mode information on the default mode (for example, mode 0) indicating that the battery module is not operating in any mode. Accordingly, the battery management system 10 may determine that the battery module 20_i is performing no operation, determine the operation required for the battery module 20_i, and generate a control signal corresponding thereto.

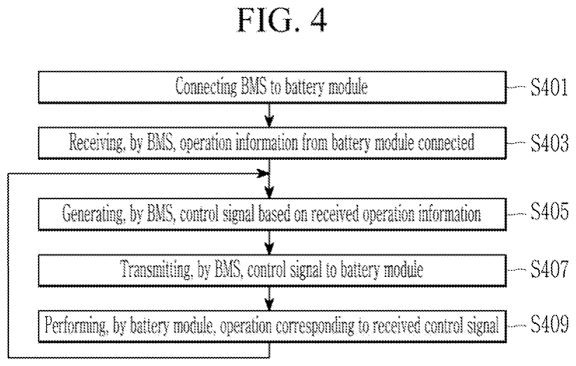

FIG. 4 illustrates an example of an operation flowchart when the battery management system 10 is connected to the battery module 20_i, in the battery apparatus 1 according to an example embodiment.

First, the battery management system 10 is connected to the battery module 20_i (S401). The battery management system 10 and the battery module 20_i may be connected through a wire. The battery management system 10 and the battery module 20_i may transmit and receive data through, e.g., UART communication or CAN communication.

Next, the battery management system 10 receives operation information of the battery module 20_i from the battery module 20_i connected thereto (S403). The operation information may be information on an operation state being performed by the battery module 20_i, and may include mode information and task information about a task to be performed or being performed by the battery module 20_i in each mode. Furthermore, the operation information may include information about a temperature of the battery cell 210_i in the battery module 20_i, a voltage of the battery cell 210_i, and the like. One mode may include a plurality of tasks of which order is predetermined.

Next, the battery management system 10 generates a control signal based on the received operation information (S405). The battery management system 10 may determine which operation the battery module 20_i is performing, and generate control signals corresponding to respective tasks to sequentially perform tasks included in the corresponding mode.

Alternatively, the battery management system 10, when there is no next operation to be performed by the battery module 20_i in the mode corresponding to the mode information, may generate a control signal for controlling to perform the first operation of the corresponding mode. The battery management system 10, when the operation information including the information on mode 0 is received from the battery module 20_i, may determine that the battery module 20_i is performing no operation. The battery management system 10 may then determine a task required for the battery module 20_i based on the operation information including information on the temperature of the battery cell 210_i in the battery module 20_i, the voltage of the battery cell 210_i, and the like, and may generate a control signal that controls to perform the corresponding task.

Next, the battery management system 10 transmits a control signal to the battery module 20_i (S407).

Next, the battery module 20_i performs an operation corresponding to the received control signal (S409).

By way of summation and review, a battery management system may transmit one instruction and then disconnect a connection with a battery module, so as to control another battery module. However, an unpredictable connection failure between the battery management system and the battery module may occur. In this case, even if the connection between the battery management system and the battery module becomes normal, the battery management system may not know which operation the battery module is performing.

As described above, an example embodiment may provide a battery management system and a battery apparatus that may control a battery module to continuously operate even when the battery management system and the battery module are disconnected and then reconnected.

A battery apparatus according to an example embodiment may control the battery module to continuously perform the operation, even in a case of an unexpected connection failure between the battery management system and the battery module.

In a battery apparatus according to an example embodiment, a battery management system may be configured in a method in which it transmits only a control signal required to the battery module, disconnects the connection, and controls other battery modules. Thus, it may be possible to control a plurality of battery modules by a relatively smaller number of battery management systems. For example, according to an example embodiment, it may be possible to control a plurality of battery modules by using one battery management system.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. The steps constituting the method according to the embodiments may be performed in an appropriate order unless explicitly stated or contradicted by the order. The present invention is not necessarily limited to the described order of steps. Accordingly, it will be understood by those of skill in the art that various changes in form and details may be made without departing from the spirit and scope of the present invention as set forth in the following claims.

What is claimed is:

1. A battery apparatus, comprising:
a battery module including a plurality of battery cells; and
a battery management system that receives operation information including mode information and task information about an operation being performed by the battery module from the battery module, and that generates a control signal with respect to the battery module based on the operation information to transmit it to a battery module connected thereto, wherein one mode includes a plurality of tasks an order of which is predetermined.

2. The battery apparatus of claim 1, wherein:
the operation information further includes information about at least one of a temperature or a voltage of a battery cell of the plurality of battery cells of the battery module, and
when the mode information indicates a default mode indicating that there is no operation being performed by the battery module, the battery management system generates a control signal based on the information about at least one of the temperature or the voltage of the battery cell.

3. The battery apparatus of claim 1, wherein, when determining that there is a next task of a task corresponding to the task information in a mode corresponding to the mode information, the battery management system generates a control signal controlling the battery module so that the battery module performs the next task.

4. The battery apparatus of claim 1, wherein, when determining that there is no next task of a task corresponding to the task information in a mode corresponding to the mode information, the battery management system generates a control signal controlling the battery module so that the battery module performs a first task of the mode corresponding to the mode information.

5. The battery apparatus of claim 1, wherein a mode corresponding to the mode information includes at least one of a battery management system initializing mode, a battery module manager initializing mode, a measurement mode, a diagnosis mode, a cell balancing mode, an error mode, or a default mode.

6. A control method of a battery apparatus, comprising:
transmitting, by a battery module including a plurality of battery cells, operation information on an operation being performed to a battery management system, wherein the operation information includes mode information and task information, and one mode includes a plurality of operations an order of which is predetermined;
generating, by the battery management system, a control signal with respect to the battery module based on the operation information; and
transmitting, by the battery management system, the control signal to the battery module.

7. The method of claim 6, wherein:
the operation information further includes information about at least one of a temperature or a voltage of a battery cell of the plurality of battery cells of the battery module,
the transmitting of the operation information to the battery management system includes transmitting, by the battery module, operation information including mode information indicating a default mode indicating that there is no operation being performed by the battery module, to the battery management system, and
the generating of the control signal includes generating, by the battery management system, a control signal based on information on at least one of a temperature or a voltage of the battery cell when the mode information indicates the default mode.

8. The method of claim 6, wherein the generating of the control signal includes generating, by the battery management system, when it is determined that there is a next task of a task corresponding to the task information in a mode corresponding to the mode information, a control signal controlling the battery module so that the battery module performs the next task.

9. The method of claim 6, wherein the generating of the control signal includes generating, by the battery management system, when it is determined that there is no next task of a task corresponding to the task information in a mode corresponding to the mode information, a control signal controlling the battery module so that the battery module performs a first task of the mode corresponding to the mode information.

10. The method of claim 6, wherein a mode corresponding to the mode information includes at least one of a battery management system initializing mode, a battery module manager initializing mode, a measurement mode, a diagnosis mode, a cell balancing mode, an error mode, or a default mode.
